(19) United States
(12) Patent Application Publication
(10) Pub. No.: US 2015/0271914 A1
(43) Pub. Date: Sep. 24, 2015

(54) INTEGRATED CIRCUIT

(71) Applicants: Ying-Jiunn Lai, Pingtung County (TW); Jung-Chi Ho, New Taipei City (TW)

(72) Inventors: Ying-Jiunn Lai, Pingtung County (TW); Jung-Chi Ho, New Taipei City (TW)

(73) Assignee: FARADAY TECHNOLOGY CORP., Hsinchu (TW)

(21) Appl. No.: 14/274,784

(22) Filed: May 12, 2014

(30) Foreign Application Priority Data
Mar. 24, 2014 (TW) 103110879

(51) Int. Cl. H05K 1/02; H05K 1/11

(52) U.S. Cl. CPC H05K 1/0233; H05K 1/0234; H05K 1/111

(57) ABSTRACT

An integrated circuit (IC) is provided. The IC includes a chip/die and a package. The chip/die includes a first bonding pad, a second bonding pad, a core circuit and a resistance unit. The first bonding pad is coupled to a signal path of the core circuit. The two ends of the resistance unit are respectively coupled to the first bonding pad and the second bonding pad. The package includes a pin and a low-pass circuit. The pin is electrically connected to the first bonding pad. The low-pass circuit is electrically connected to the second bonding pad.

### CROSS-REFERENCE TO RELATED APPLICATION

This application claims the priority benefit of Taiwan application serial no. 103110879, filed on Mar. 24, 2014. The entirety of the above-mentioned patent application is hereby incorporated by reference herein and made a part of this specification.

### BACKGROUND

1. Technical Field

The invention relates to an electronic element, and particularly relates to an integrated circuit.

2. Related Art

During a process of signal transmission, a signal in a transmission channel has a considerable loss. Therefore, an equalizer is equipped at a transmitter side and/or a receiver side to compensate the loss. For example, FIG. 1 is a circuit block schematic diagram of a signal transmission system. In a situation shown in FIG. 1, differential signals output by a transmitter 110 are transmitted to a receiver 130 through a transmission channel 120. During the process of signal transmission, the signal in the transmission channel 120 has a considerable loss. For example, according to a characteristic curve of gain G and frequency f of the transmission channel 120 shown in FIG. 1, the signal gain G in the transmission channel 120 is decreased as the frequency f is increased, which is similar to the effect of a low-pass filter. Therefore, an equalizer 112 used for compensating the loss can be added to the transmitter 110 to gain a high frequency part of the differential signal output by a transmitter core circuit 111. Similarly, an equalizer 131 used for compensating the loss can be added to the receiver 130 to gain the high frequency part of the differential signal come from the transmission channel 120, and transmit the equalized differential signal to a receiver core circuit 132. To be specific, a high pass filter is configured to a signal path of the transmitter 110 and/or the receiver 130 to gain the high frequency part of the differential signal, so as to implement loss compensation and/or band compensation of the differential signal.

### SUMMARY

The invention is directed to an integrated circuit, which improves transmission integrity of differential signals or a single-end signal at a transmitter and/or a receiver.

An embodiment of the invention provides an integrated circuit including a chip/die and a package. The chip/die includes a first bonding pad, a second bonding pad, a core circuit and a first resistance unit. The first bonding pad is coupled to a first signal path of the core circuit. Two ends of the first resistance unit are respectively coupled to the first bonding pad and the second bonding pad. The chip/die is disposed in the package. The package includes a first pin and a low-pass circuit. The first pin is electrically connected to the first bonding pad. A first terminal of the low-pass circuit is electrically connected to the second bonding pad.

According to the above description, the integrated circuit is configured to have a passive equalizer function of adaptive bandwidth, so as to improve transmission integrity of a differential signal or a single-end signal. By using the resistance unit configured in the chip/die and the passive low-pass circuit configured in the package structure, the passive equalizer function with adjustable frequency response characteristic is implemented.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a circuit block schematic diagram of a signal transmission system.

FIG. 2 is a schematic diagram of an integrated circuit (IC) according to an embodiment of the invention.

FIG. 3A is a schematic diagram of an IC according to another embodiment of the invention.

FIG. 3B is a schematic diagram of design parameters of a bonding wire.

FIG. 4-FIG. 14 are schematic diagrams of ICs according to different embodiment of the invention.

### DETAILED DESCRIPTION OF DISCLOSED EMBODIMENTS

A term “couple” used in the full text of the disclosure (including the claims) refers to any direct and indirect connections. For example, if a first device is described to be coupled to a second device, it is interpreted as that the first device is directly coupled to the second device, or the first device is indirectly coupled to the second device through other devices or connection means. Moreover, wherever possible, components/members/steps using the same referential numbers in the drawings and description refer to the same or like parts. Components/members/steps using the same referential numbers or using the same terms in different embodiments may cross-refer related descriptions.

FIG. 2 is a schematic diagram of an integrated circuit (IC) according to an embodiment of the invention. The IC shown in FIG. 2 includes a chip/die 210 and a package 220. The chip/die 210 is disposed in the package 220. The method of disposing the chip/die 210 in the package 220 is not limited by the invention. For example, in the present embodiment, a lead-frame packaging process, a ball grid array (BGA) packaging process, a flip-chip packaging process or other packaging methods can be used to dispose the chip/die 210 in the package 220.

The chip/die 210 includes a first bonding pad PAD1, a second bonding pad PAD2, a core circuit 211 and a first resistance unit 212, where the first bonding pad PAD1 is coupled to a first signal path of the core circuit 211. The first resistance unit 212 includes a fixed resistor or a variable resistor or an MOS resistor, or a resistance element implemented in the chip/die in any form. Two ends of the first resistance unit 212 are respectively coupled to the first bonding pad PAD1 and the second bonding pad PAD2. The package 220 includes a first pin PIN1 and a low-pass circuit 221. The first bonding pad PA1, the second bonding pad PAD2, the core circuit 211 and the first resistance unit 212 in the chip/die 210 can be fabricated through any chip manufacturing process. The low-pass circuit 221 can be fabricated through any non-chip manufacturing process, for example, a packaging process or a surface-mounting device (SMD) process. The first pin PIN1 is electrically connected to the first bonding pad PAD1. In the present embodiment, a connection method between the first bonding pad PAD1 and the first pin PIN1 is not limited by the invention. In some embodiments, the first bonding pad PAD1 can be connected to the first pin PIN1 through a wire bonding manner. In some other embodiments, the first bonding pad PAD1 and the first pin PIN1 can be connected through a conductive bump or by using other methods. A first terminal of the low-pass circuit 221 is electrically connected to the second bonding pad PAD2. The connection method between the second bonding pad PAD2 and the low-pass circuit 221 can be deduced according to related description of the first bonding pad PAD1.

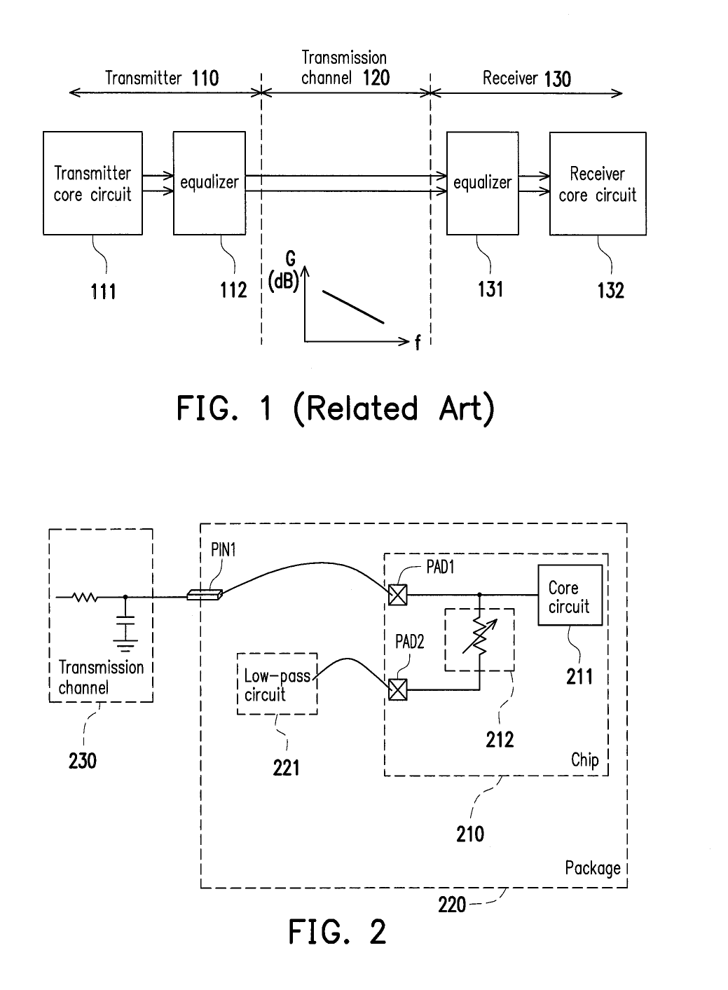

Description of a transmission channel 230 can be deduced according to related description of the transmission channel 120 of FIG. 1. In different application situations, the transmission channel 230 can be a signal wire on a printed circuit board (PCB), or a cable wire (for example, a coaxial cable, an Ethernet cable or other cables). Signals can be transmitted through the transmission channel 230. For example, signals output by the core circuit 211 can be transmitted to a receiver circuit (not shown) through the first bonding pad PAD1, the first pin PIN1 and the transmission channel 230. For another example, signals output by a transmitter circuit (not shown) can be transmitted to the core circuit 211 through the transmission channel 230, the first pin PIN1 and the first bonding pad PAD1.

Generally, the transmission channel 230 has a characteristic of a low-pass filter. Namely, a signal gain in the transmission channel 230 is decreased along with increase of signal frequency. By using the first resistance unit 212 of the chip/die 210 and the low-pass circuit 221 of the package 220, a gain amount of the low-frequency component of the signal on the first bonding pad PAD1 is decreased. Therefore, the IC shown in FIG. 2 may have a passive equalizer function, so as to improve signal transmission integrity. In some other embodiments, a resistance of the first resistance unit 212 can be adjusted to implement the passive equalizer function of adaptive bandwidth, so as to adjust a frequency response characteristic thereof.

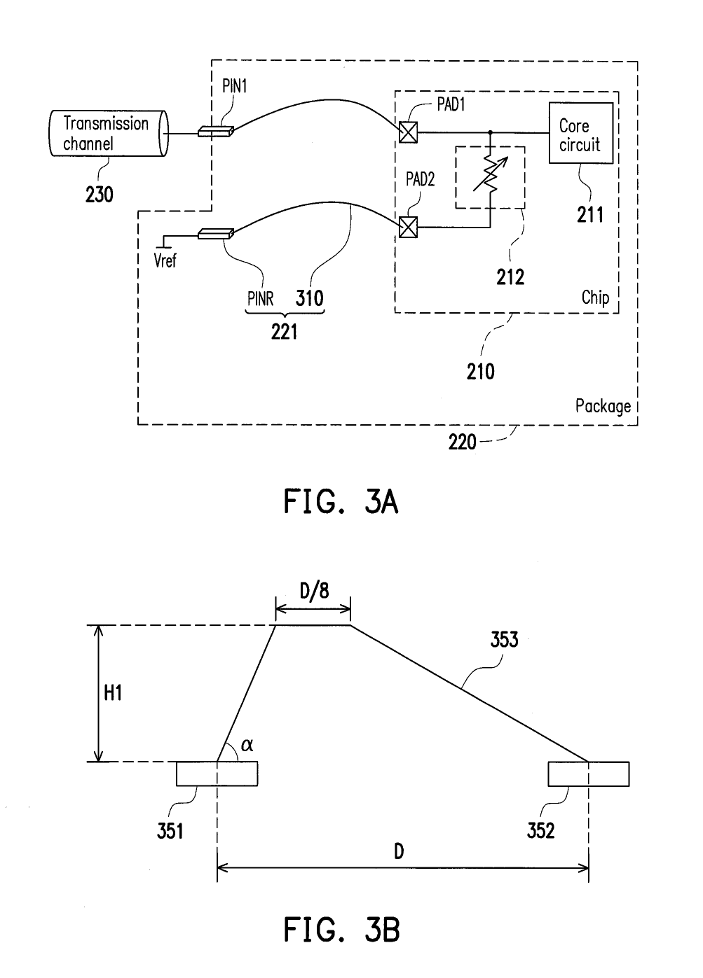

FIG. 3A is a schematic diagram of an IC according to another embodiment of the invention. Description of the embodiment of FIG. 3A can be deduced according to related description of the embodiment of FIG. 2. In the embodiment of FIG. 3A, the low-pass circuit 221 includes a reference pin PINR and a bonding wire 310. The reference pin PINR can be coupled to a reference voltage Vref (for example, a ground voltage or other fixed voltage). In the embodiment of FIG. 3A, the reference voltage Vref can be provided by a regulator in internal of the chip/die 210 (or in internal of the package 220). In other embodiments, the reference voltage Vref can also be provided by a voltage source outside the package 220. Two ends of the bonding wire 310 are electrically connected to the second bonding pad PAD2 of the chip/die 210 and the reference pin PINR of the package 220, respectively. A parasitic inductance of the bonding wire 310 can be regarded as a low-pass element. Therefore, a gain amount of the low frequency component of the signal on the first bonding pad PAD1 is decreased. By adjusting a resistance of the resistance unit 212, the IC shown in FIG. 3A can implement the passive equalizer function of adaptive bandwidth, so as to adjust a frequency response characteristic of the equalizer.

By adjusting design parameters of the bonding wire 310, the parasitic inductance of the bonding wire 310 can be adjusted. FIG. 3B is a schematic diagram of the design parameters of the bonding wire 310. Two ends of the bonding wire 353 of FIG. 3B are electrically connected to a bonding pad 351 of the chip/die and a bonding pad 352 of the package, respectively. D represents a distance between the bonding pad 351 of the chip/die and the bonding pad 352 of the package. The bonding wires (for example, the bonding wire 310 shown in FIG. 3A) mentioned in the present embodiment of the invention can also be deduced according to related description of FIG. 3B. Referring to FIG. 3B, by adjusting a wire length, a wire diameter, a material, an arc height H1 and/or an arc angle α, the parasitic inductance of the bonding wire 353 can be adjusted. For example, the wire length of the bonding wire 353 is, 0-12 mm, and a wire diameter of the bonding wire 353 is not limited (for example, 0.018 mm or other wire diameters). The material of the bonding wire 353 can be aluminium, copper, gold, silver or other metal/alloy. The arc height H1 of the bonding wire 353 is smaller than 1.5 mm, and the arc angle α of the bonding wire 353 is between 0° to 90°.

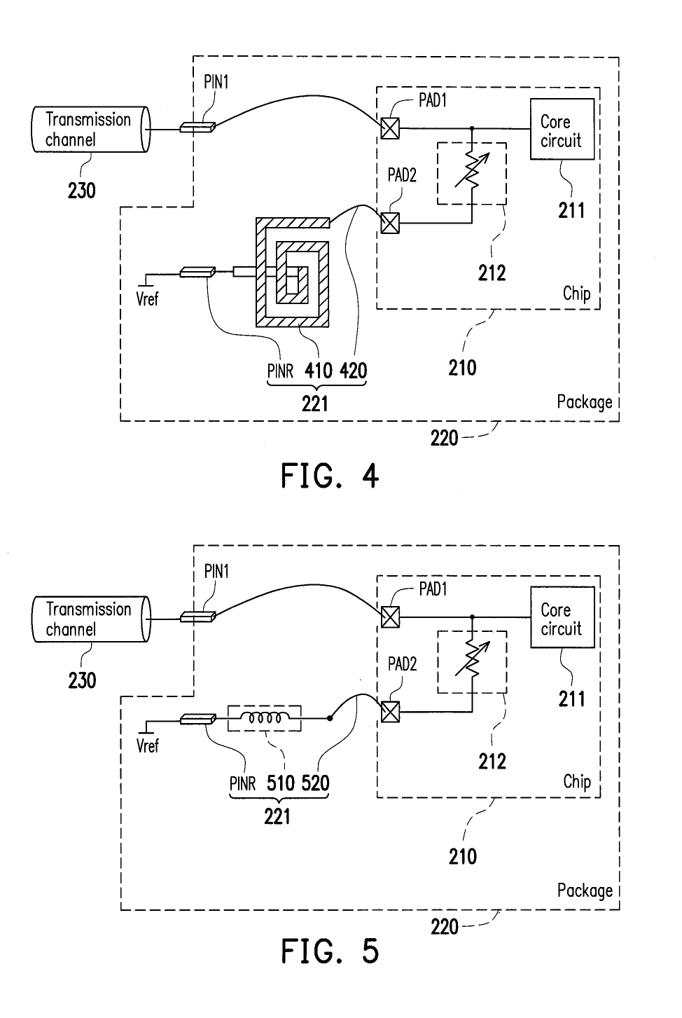

FIG. 4 is a schematic diagram of an IC according to still another embodiment of the invention. The embodiment of FIG. 4 can be deduced according to related description of FIG. 2, in the embodiment of FIG. 4, the low-pass circuit 221 includes a reference pin PINR, a high impedance wire 410 and a bonding wire 420. The reference pin PINR can be coupled to the reference voltage Vref (for example, the ground voltage or other fixed voltage). In the embodiment of FIG. 4, the reference voltage Vref can be provided by a regulator in internal of the chip/die 210 (or in internal of the package 220). In other embodiments, the reference voltage Vref can be provided by a voltage source outside the package 220. An impedance value of the high impedance wire 410 can be determined according to an actual design requirement, for example, a characteristic impedance value of the high impedance wire 410 can be set to be greater than 70 ohm. A first end of the high impedance wire 410 is coupled o the reference pin PINR to receive the reference voltage Vref. Two ends of the bonding wire 420 are electrically connected to the second bonding pad PAD2 of the chip/die 210 and a second end of the high impedance wire 410. A layout structure and a geometric shape of the high impedance wire 410 are not limited by the invention. The high impedance wire 410 can be set in a shape of a coil. The layout structure of the high impedance wire 410 has an inductance effect to provide an inductance. Therefore, the high impedance wire 410 can be regarded as a low-pass element to decrease a gain amount of the low frequency component of the signal on the first bonding pad PAD1. By adjusting the resistance of the resistance unit 212, the IC shown in FIG. 4 can implement the passive equalizer function of adaptive bandwidth, so as to adjust a frequency response characteristic of the equalizer.

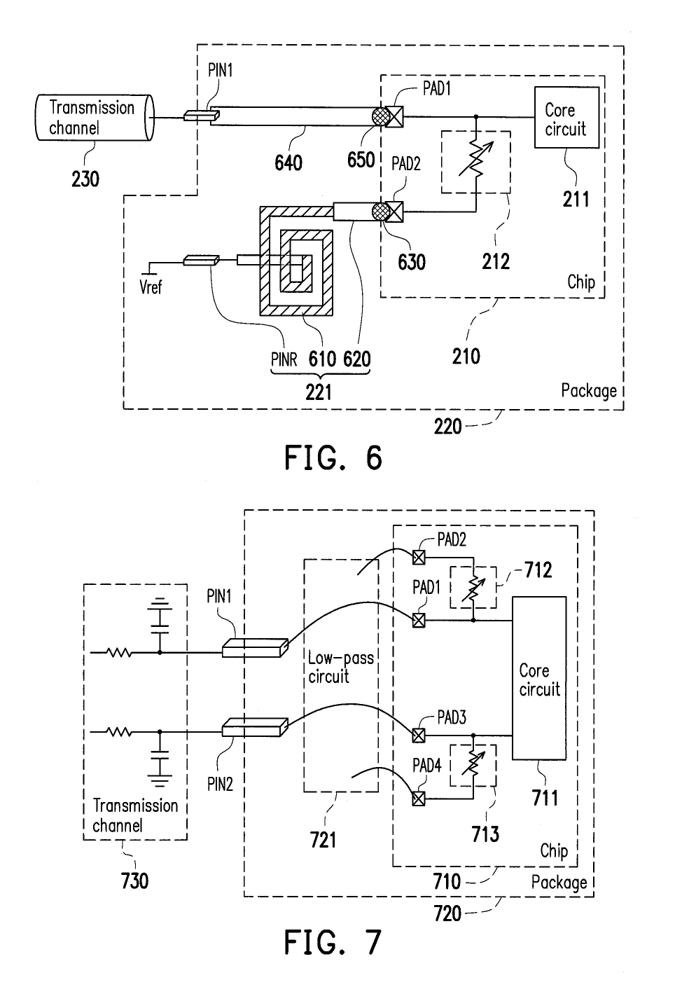

FIG. 5 is a schematic diagram of an IC according to still another embodiment of the invention. The embodiment of FIG. 5 can be deduced according to related description of the embodiment of FIG. 2. In the embodiment of FIG. 5, the low-pass circuit 221 includes a reference pin PINR, an inductor 510 and a bonding wire 520. The reference pin PINR can be coupled to the reference voltage Vref (for example, the ground voltage or other fixed voltage). In the embodiment of FIG. 5, the reference voltage Vref can be provided by a regulator in internal of the chip/die 210 (or in internal of the package 220). In other embodiments, the reference voltage Vref can be provided by a voltage source outside the package 220. An inductance of the inductor 510 can be determined according to an actual design requirement, for example, the inductance of the inductor 510 is set to be smaller than 100 nH. A first end of the inductor 510 is coupled to the reference pin PINR to receive the reference voltage Vref. Two ends of the bonding wire 520 are electrically connected to the second bonding pad PAD2 of the chip/die 210 and a second end of the inductor 510 of the package 220. The inductor 510 can be an SMD or other types of inductor. The inductor 510 can be regarded as a low-pass element to decrease a gain amount of the low frequency component of the signal on the first bonding pad PAD1. By adjusting the resistance of the resistance unit 212, the IC shown in FIG. 5 can implement the passive equalizer function of adaptive bandwidth, so as to adjust a frequency response characteristic of the equalizer.

FIG. 6 is a schematic diagram of an IC according to still another embodiment of the invention. The embodiment of FIG. 6 can be deduced according to related descriptions of the embodiments of FIG. 2 and FIG. 4. In the embodiment of FIG. 6, the low-pass circuit 221 includes a reference pin PINR, a high impedance wire 610 and a low impedance wire 620. The reference pin PINR can be coupled to the reference voltage Vref (for example, the ground voltage or other fixed voltage). In the embodiment of FIG. 6, the reference voltage Vref can be provided by a regulator in internal of the chip/die 210 (or in internal of the package 220). In other embodiments, the reference voltage Vref can be provided by a voltage source outside the package 220. A first end of the high impedance wire 610 is coupled to the reference pin PINR for receiving the reference voltage Vref. A second end of the high impedance wire 610 is coupled to a first end of the low impedance wire 620. A second end of the low impedance wire 620 is electrically connected to the second bonding pad PAD2 of the chip/die 210 through a conductive bump 630. In another embodiment, the low impedance wire 620 can be omitted. In case that the low impedance wire 620 is omitted, the second end of the high impedance wire 610 is directly coupled to the conductive bump 630, such that the second end of the high impedance wire 610 is electrically connected to the second bonding pad PAD2 of the chip/die 210 through the conductive bump 630. A first end of a low impedance wire 640 is coupled to the first pin PIN1. A second end of the low impedance wire 640 is electrically connected to the first bonding pad PAD1 of the chip/die 210 through a conductive bump 650. Impedance values of the high impedance wire and the low impedance wire can be determined according to an actual design requirement, for example, the characteristic impedance values of the high impedance wire and the low impedance wire are respectively set to be greater than or smaller than 70 ohm.

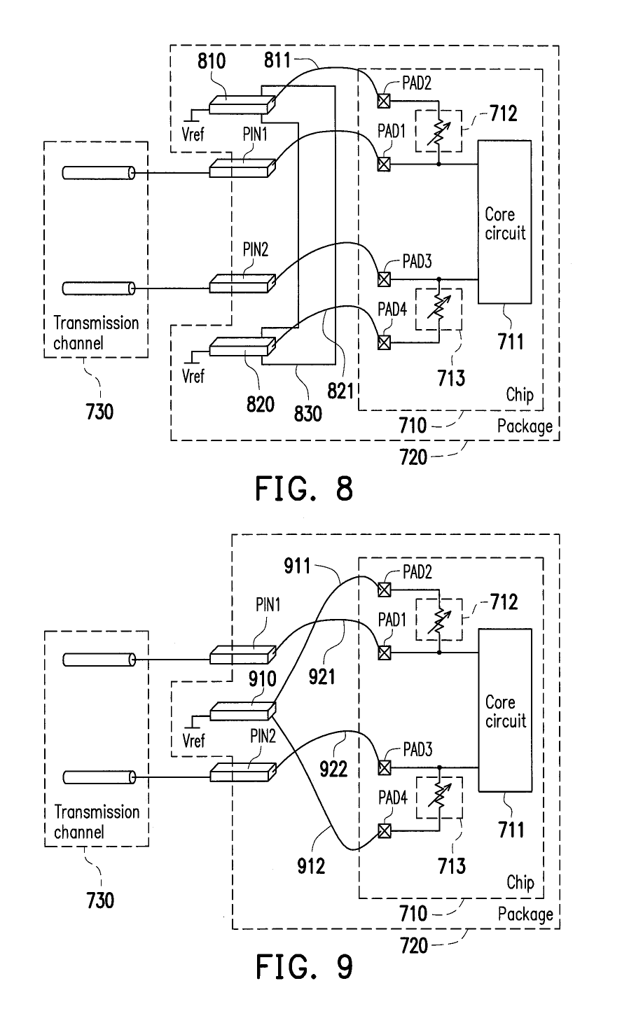

FIG. 7 is a schematic diagram of an IC according to still another embodiment of the invention. The embodiment of FIG. 7 can be deduced according to related descriptions of the embodiments of FIG. 2 to FIG. 6. The IC shown in FIG. 7 includes a chip/die 710 and a package 720. The chip/die 710 is disposed in the package. The method of disposing the chip/die 710 in the package 720 is not limited by the invention. For example, in the present embodiment, a lead-frame packaging process, a ball grid array (BGA) packaging process, a flip-chip packaging process or other packaging methods can be used to dispose the chip/die 710 in the package 720.

The chip/die 710 includes a first bonding pad PAD1, a second bonding pad PAD2, a third bonding pad PAD3, a fourth bonding pad PAD4, a core circuit 711, a first resistance unit 712 and a second resistance unit 713. The first bonding pad PAD1 and the third bonding pad PAD3 are disposed between the second bonding pad PAD2 and the fourth bonding pad PAD4. The first bonding pad PAD1 is coupled to a first signal path of the core circuit 711, and the third bonding pad PAD3 is coupled to a second signal path of the core circuit 711, where the first signal path and the second signal path are mutual differential signal pair. The first resistance unit 712 and the second resistance unit 713 respectively includes a fixed resistor or a variable resistor. Two ends of the first resistance unit 712 are respectively coupled to the first bonding pad PAD1 and the second bonding pad PAD2. Two ends of the second resistance unit 713 are respectively coupled to the third bonding pad PAD3 and the fourth bonding pad PAD4.

The package 720 includes a first pin PIN1, a second pin PIN2 and a low-pass circuit 721. The first bonding pad PA1, the second bonding pad PAD2, the third bonding pad PAD3, the fourth bonding pad PAD4, the core circuit 711, the first resistance unit 712 and the second resistance unit 713 in the chip/die 710 can be fabricated through any chip manufacturing process. The low-pass circuit 721 in the package 720 can be fabricated through any non-chip manufacturing process, for example, a packaging process or a surface-mounting device (SMD) process. The first pin PIN1 is electrically connected to the first bonding pad PAD1, and the second pin PIN2 is electrically connected to the third bonding pad PAD3. A first terminal and a second terminal of the low-pass circuit 721 are electrically connected to the second bonding pad PAD2 and the fourth bonding pad PAD4, respectively.

In the present embodiment, a connection method between the bonding pads and the pins are not limited by the invention. In some embodiments, the first bonding pad PAD1 can be electrically connected to the first pin PIN1 through a wire bonding manner, and the third bonding pad PAD3 is also electrically connected to the second pin PIN2 through the same manner. In some other embodiments, the bonding pads and the pins can be connected through conductive bumps or by using other methods. The bonding pad and the low-pass circuit 721 can be connected through wire bonding, conductive bump or other connection methods.

Description of a transmission channel 730 can be deduced according to related description of the transmission channel 120 of FIG. 1 or the transmission channel 230 of FIG. 2. In different application situations, the transmission channel 730 can be a signal wire on a printed circuit board (PCB), or a cable wire (for example, a coaxial cable, an Ethernet cable or other cables). Signals can be transmitted through the transmission channel 730. For example, differential signals output by the core circuit 711 can be transmitted to a receiver circuit (not shown) through the first bonding pad PAD1, the third bonding pad PAD3, the first pin PIN1, the second pin PIN2 and the transmission channel 730. For another example, signals output by a transmitter circuit (not shown) can be transmitted to the core circuit 711 through the transmission channel 730, the first pin PIN1, the second PIN PIN2, the first bonding pad PAD1 and the third bonding pad PAD3.

Generally, the transmission channel 730 has a characteristic of a low-pass filter. Namely, a signal gain in the transmission channel 730 is decreased along with increase of signal frequency. By using the first resistance unit 712, the second resistance unit 713 of the chip/die 710 and the low-pass circuit 721 of the package 720, a gain amount of the low-frequency component of the differentials signal on the first bonding pad PAD1 and the third bonding pads PAD3e is decreased. Therefore, the IC shown in FIG. 7 may have a passive equalizer function, so as to improve signal transmission integrity. In some other embodiments, resistances of the first resistance unit 712 and the second resistance unit 713 can be adjusted to implement the passive equalizer function of adaptive bandwidth, so as to adjust a frequency response characteristic thereof.

FIG. 8 is a schematic diagram of an IC according to still another embodiment of the invention. Description of the embodiment of FIG. 8 can be deduced according to related description of the embodiment of FIG. 7. In the embodiment of FIG. 8, the low-pass circuit 721 includes a pin 810, a pin 820, a bonding wire 811 and a bonding wire 821. Two ends of the bonding wire 811 are electrically connected to the second bonding pad PAD2 of the chip/die 710 and a first end of a low impedance wire 830 of the package 720, respectively. Two ends of the bonding wire 821 are electrically connected to the fourth bonding pad PAD4 of the chip/die 710 and a second end of the low impedance wire 830 of the package 720, respectively. The pin 810 is electrically connected to the first end of the low impedance wire 830. The pin 820 is electrically connected to the second end of the low impedance wire 830. The pin 810 and the pin 820 are coupled to the reference voltage Vref (for example, the ground voltage or other fixed voltage). In the embodiment of FIG. 8, the reference voltage Vref can be provided by a regulator in internal of the chip/die 710 (or in internal of the package 720). In other embodiments, the reference voltage Vref can also be provided by a voltage source outside the package 720.

In another embodiment, the pin 810 and the pin 820 can be floated (which are not coupled to the reference voltage Vref). In other embodiments, the reference voltage Vref, the pin 810 and the pin 820 can be omitted.

By adjusting design parameters of the bonding wire 811 and the bonding wire 821, parasitic inductances thereof can be adjusted (referring to related description of FIG. 3B). The parasitic inductance of the bonding wire 811 and the parasitic inductance of the bonding wire 821 can be regarded as low-pass elements. Therefore, a gain amount of the low frequency component of the differential signals on the first bonding pad PAD1 and the third bonding pads PAD3 is decreased. By adjusting resistances of the resistance unit 712 and the resistance unit 713, the IC shown in FIG. 8 can implement the passive equalizer function of adaptive bandwidth, so as to adjust a frequency response characteristic of the equalizer.

FIG. 9 is a schematic diagram of an IC according to still another embodiment of the invention. The embodiment of FIG. 9 can be deduced according to related description of FIG. 7 and FIG. 8. Two ends of a bonding wire 921 are electrically connected to the first bonding pad PAD1 of the chip/die 710 and the pin PIN1 of the package 720. Two ends of a bonding wire 922 are electrically connected to the third bonding pad PAD3 of the chip/die 710 and the pin PIN2 of the package 720. In the embodiment of FIG. 9, the low-pass circuit 721 includes a pin 910, a bonding wire 911 and a bonding wire 912. The bonding wire 911 and the bonding wire 921 do not contact each other, and the bonding wire 912 and the bonding wire 922 do not contact each other. Two ends of the bonding wire 911 are electrically connected to the second bonding pad PAD2 of the chip/die 710 and a pin 910 of the package 720. Two ends of the bonding wire 912 are electrically connected to the fourth bonding pad PAD4 of the chip/die 710 and the pin 910 of the package 720. The pin 910 is coupled to the reference voltage Vref (for example, the ground voltage or other fixed voltage). In the embodiment of FIG. 9, the reference voltage Vref can be provided by a regulator in internal of the chip/die 710 (or in internal of the package 720). In other embodiments, the reference voltage Vref can be provided by a voltage source outside the package 720. In another embodiment, the pin 910 can be floated (which is not coupled to the reference voltage Vref). By adjusting design parameters of the bonding wire 911 and the bonding wire 912, parasitic inductances thereof can be adjusted (referring to related description of FIG. 3B). The parasitic inductance of the bonding wire 911 and the parasitic inductance of the bonding wire 912 can be regarded as low-pass elements. Therefore, a gain amount of the low frequency component of the differential signals on the first bonding pad PAD1 and the third bonding pads PAD3 is decreased.

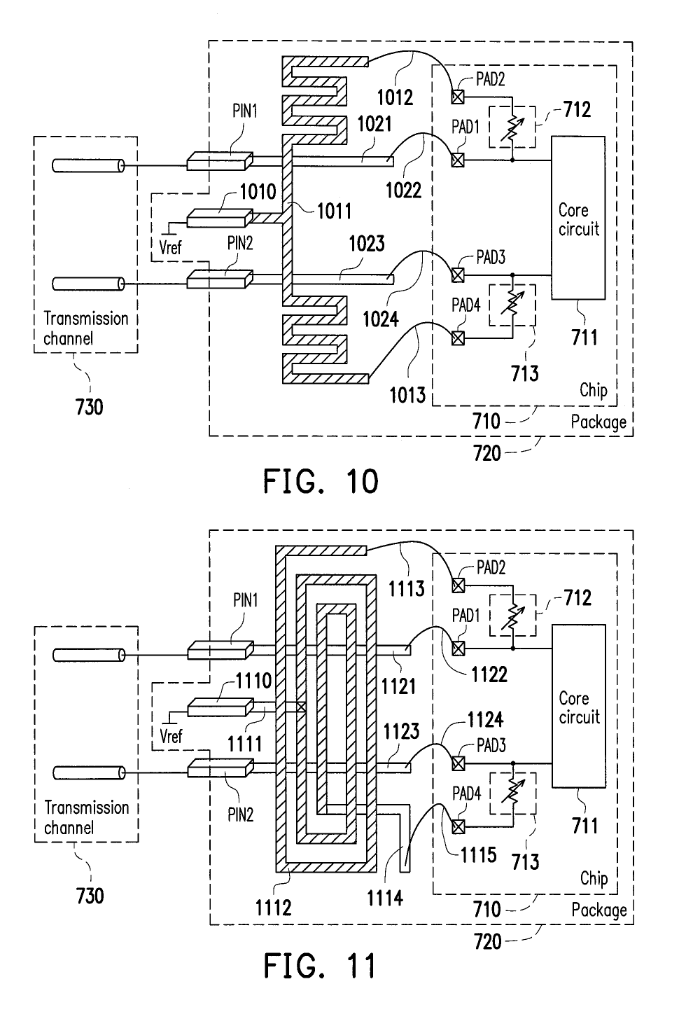

FIG. 10 is a schematic diagram of an IC according to still another embodiment of the invention. The embodiment of FIG. 10 can be deduced according to related description of FIG. 7. The first bonding pad PAD1 of the chip/die 710 is electrically connected to the pin PIN1 of the package 720 through a bonding wire 1022 and a low impedance wire 1021. The third bonding pad PAD3 of the chip/die 710 is electrically connected to the pin PIN2 of the package 720 through a bonding wire 1024 and a low impedance wire 1023. In the embodiment of FIG. 10, the low-pass circuit 721 includes a pin 1010, a high impedance wire 1011, a bonding wire 1012 and a bonding wire 1013. Moreover, in an application of a flip chip bonding process, the bonding wires 1012, 1013, 1022 and 1024 shown in FIG. 10 can be replaced by different conductive bumps.

The low impedance wires 1021 and 1023 are configured to a first conductive layer of the package 720, and the high impedance wire 1011 is configured to a second conductive layer of the package 720, such that the low impedance wires 1021 and 1023 do not contact the high impedance wire 1011. In other embodiments, the low impedance wires 1021 and 1023 and the high impedance wire 1011 can be configured to a same conductive layer of the package 720, where the low impedance wires 1021 and 1023 do not contact the high impedance wire 1011. Two ends of the bonding wire 1012 are electrically connected to the second bonding pad PAD2 of the chip/die 710 and a first end of the high impedance wire 1011 of the package 720, respectively. Two ends of the bonding wire 1013 are electrically connected to the fourth bonding pad PAD4 of the chip/die 710 and a second end of the high impedance wire 1011 of the package 720, respectively. A central end of the high impedance wire 1011 is electrically connected to the pin 1010. The pin 1010 can be coupled to the reference voltage Vref (for example, the ground voltage or other fixed voltage). In the embodiment of FIG. 10, the reference voltage Vref can be provided by a regulator in internal of the chip/die 710 (or in internal of the package 720). In other embodiments, the reference voltage Vref can be provided by a voltage source outside the package 720. The parasitic inductances of the bonding wire 1011, the bonding wire 1012 and the bonding wire 1013 can be regarded as low-pass elements. Therefore, a gain amount of the low frequency component of the differential signals on the first bonding pad PAD1 and the third bonding pads PAD3 is decreased.

In another embodiment, the pin 1010 can be floated (which is not coupled to the reference voltage Vref). In other embodiments, the pin 1010 can be omitted.

FIG. 11 is a schematic diagram of an IC according to still another embodiment of the invention. The embodiment of FIG. 11 can be deduced according to related description of FIG. 7. The first bonding pad PAD1 of the chip/die 710 is electrically connected to the pin PIN1 of the package 720 through a bonding wire 1122 and a low impedance wire 1121. The third bonding pad PAD3 of the chip/die 710 is electrically connected to the pin PIN2 of the package 720 through a bonding wire 1124 and a low impedance wire 1123. In the embodiment of FIG. 11, the low-pass circuit 721 includes a pin 1110, a low impedance wire 1111, a high impedance wire 1112, a bonding wire 1113, a low impedance wire 1114 and a bonding wire 1115. The low impedance wires 1111, 1114, 1121 and 1123 are configured to a first conductive layer of the package 720, and the high impedance wire 1112 is configured to a second conductive layer of the package 720, so that the low impedance wires 1121 and 1123 do not contact the high impedance wires 1112. In other embodiments, the low impedance wires 1121 and 1123 and the high impedance wire 1112 can be configured to a same conductive layer in the package 720, where the low impedance wires 1121 and 1123 do not contact the high impedance wire 1112. Two ends of the bonding wire 1113 are electrically connected to the second bonding pad PAD2 of the chip/die 710 and a first end of the high impedance wire 1112 of the package 720, respectively. Two ends of the bonding wire 1115 are electrically connected to the fourth bonding pad PAD4 of the chip/die 710 and a first end of the low impedance wire 1114 of the package 720, respectively. A second end of the low impedance wire 1114 is connected to a second end of the high impedance wire 1112. A central end of the high impedance wire 1112 is connected to a first end of the low impedance wire 1111. A second end of the low impedance wire 1111 is connected to the pin 1110. The pin 1110 can be coupled to the reference voltage Vref (for example, the ground voltage or other fixed voltage). In the embodiment of FIG. 11, the reference voltage Vref can be provided by a regulator in internal of the chip/die 710 (or in internal of the package 720). In other embodiments, the reference voltage Vref can be provided by a voltage source outside the package 720.

The high impedance wire 1112 can provide an inductance. In the present embodiment, a layout structure and a geometric shape of the high impedance wire 1112 are not limited by the invention. For example, the high impedance wire 1112 can be set in a shape of a coil. Therefore, the high impedance wire 1112 can be regarded as a low-pass element. Therefore, a gain amount of the low frequency component of the differential signals on the first bonding pad PAD1 and the third bonding pads PAD3 is decreased.

In the embodiment of FIG. 11, a center-tapped terminal of the coil formed by the high impedance wire 1112 is electrically connected to the pin 1110 for receiving the reference voltage Vref. In another embodiment, the pin 1110 can be floated (which is not coupled to the reference voltage Vref). In other embodiments, the pin 1110 and the low impedance wire 1111 can be omitted. Moreover, in an application of a flip chip bonding process, the bonding wires 1113, 1115, 1122 and 1124 shown in FIG. 11 can be replaced by different conductive bumps.

FIG. 12 is a schematic diagram of an IC according to still another embodiment of the invention. The embodiment of FIG. 12 can be deduced according to related description of FIG. 7. The first bonding pad PAD1 of the chip/die 710 is electrically connected to the pin PIN1 of the package 720 through a bonding wire 1222 and a low impedance wire 1221. The third bonding pad PAD3 of the chip/die 710 is electrically connected to the pin PIN2 of the package 720 through a bonding wire 1224 and a low impedance wire 1223. In the embodiment of FIG. 12, the low-pass circuit 721 includes a pin 1210, an inductor 1211, a bonding wire 1212 and a bonding wire 1213. The low impedance wires 11221 and 1223 are configured to a first conductive layer of the package 720, and the inductor 1211 is configured to a second conductive layer of the package 720, so that the low impedance wires 1221 and 1223 do not contact the inductor 1211. In other embodiments, the low impedance wires 1221 and 1223 and the inductor 1211 can be configured to a same conductive layer in the package 720, where the low impedance wires 1221 and 1223 do not contact the inductor 1211. Two ends of the bonding wire 1212 are electrically connected to the second bonding pad PAD2 of the chip/die 710 and a first end of the inductor 1211 of the package 720, respectively. Two ends of the bonding wire 1213 are electrically connected to the fourth bonding pad PAD4 of the chip/die 710 and a second end of the inductor 1211 of the package 720, respectively.

In the embodiment of FIG. 12, a center-tapped terminal of the inductor 1211 is electrically connected to the pin 1210. The pin 1210 can be coupled to the reference voltage Vref (for example, the ground voltage or other fixed voltage). In the embodiment of FIG. 12, the reference voltage Vref can be provided by a regulator in internal of the chip/die 710 (or in internal of the package 720). In other embodiments, the reference voltage Vref can be provided by a voltage source outside the package 720. In another embodiment, the pin 1210 can be floated (which is not coupled to the reference voltage Vref). In other embodiments, the pin 1210 can be omitted.

An inductance of the inductor 1211 can be determined according to an actual design requirement, for example, the inductance of the inductor 1211 is set to be smaller than 100 nH. The center-tapped terminal of the inductor 1211 is coupled to the pin 1210 for receiving the reference voltage Vref. The inductor 1211 can be an SMD or other types of inductor. The inductor 1211 can be regarded as a low-pass element to decrease a gain amount of the low frequency component of the differential signals on the first bonding pad PAD1 and the third bonding pad PAD3. By adjusting the resistances of the resistance units 712 and 713, the IC shown in FIG. 12 can implement the passive equalizer function of adaptive bandwidth, so as to adjust a frequency response characteristic of the equalizer.

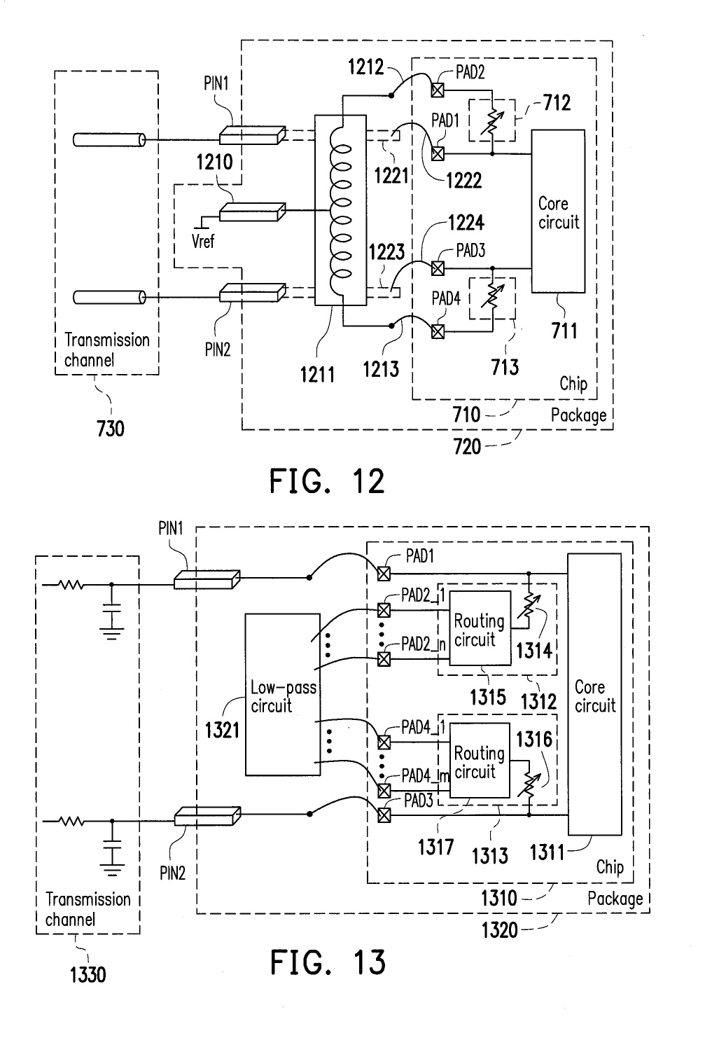

FIG. 13 is a schematic diagram of an IC according to still another embodiment of the invention. The embodiment of FIG. 13 can be deduced according to related descriptions of FIG. 2 to FIG. 12. The IC shown in FIG. 13 includes a chip/die 1310 and a package 1320. The chip/die 1310 is disposed in the package 1320. The method of disposing the chip/die 1310 in the package 1320 is not limited by the invention. For example, in the present embodiment, a lead-frame packaging process, a ball grid array (BGA) packaging process, a flip-chip packaging process or other packaging methods can be used to dispose the chip/die 1310 in the package 1320.

The chip/die 1310 includes a first bonding pad PAD1, second bonding pads PAD2_1-PAD2_{—}n, a third bonding pad PAD3, fourth bonding pads PAD4_1-PAD4_{—}m, a core circuit 1311, a first resistance unit 1312 and a second resistance unit 1313. The first bonding pad PAD1 is coupled to a first signal path of the core circuit 1311, and the third bonding pad PAD3 is coupled to a second signal path of the core circuit 1311, where the first signal path and the second signal path are mutual differential signal pair. The second pads PAD2_1-PAD2_{—}n are electrically connected to a plurality of first terminals of the low-pass circuit 1321 in the package 1320 according to a predetermined connection relationship. The fourth pads PAD4_1-PAD4_{—}n are electrically connected to a plurality of second terminals of the low-pass circuit 1321 in the package 1320 according to the predetermined connection relationship. In the present embodiment, a connection method between the bonding pads and the pins is not limited by the invention. In some embodiments, the bonding pads of the chip/die 1310 can be connected to the pins of the package 1320 through wire bonding. In some other embodiments, the bonding pads and the pins can be connected through conductive bumps or by using other methods.

The first resistance unit 1312 includes a resistor 1314 and a routing circuit 1315. A first end of the resistor 1314 is coupled to the first bonding pad PAD1. A common terminal of the routing circuit 1315 is coupled to a second end of the resistor 1314. A plurality of selection terminals of the routing circuit 1315 are coupled to the second bonding pads PAD2_1-PAD2_{—}n in a one-to-one manner. The routing circuit 1315 can couple the common terminal thereof to one or a plurality of the selection terminals of the routing circuit 1315. In collaboration with wire bonding of the second bonding wires PAD2_1-PAD2_{—}n, the routing circuit 1315 can adjust a serial/parallel configuration state of the wire bonding, so as to adjust an equivalent inductance to determine the impedance. The second resistance unit 1313 includes a resistor 1316 and a routing circuit 1317. A first end of the resistor 1316 is coupled to the third bonding pad PAD3. A common terminal of the routing circuit 1317 is coupled to a second end of the resistor 1316. A plurality of selection terminals of the routing circuit 1317 are coupled to the fourth bonding pads PAD4_1-PAD4_{—}n in the one-by-one manner. The routing circuit 1317 can couple the common terminal thereof to one or a plurality of the selection terminals of the routing circuit 1317. In collaboration with wire bonding of the fourth bonding wires PAD4_1-PAD4_{—}n, the routing circuit 1317 can adjust a serial/parallel resistance state of the wire bonding, so as to adjust an equivalent inductance to determine the impedance.

The package 1320 includes the first pin PIN1, the second pin PIN2 and the low-pass circuit 1321. The first bonding pad PAD1, the second bonding pads PAD2_1-PAD2_{—}n, the third bonding pad PAD3, the fourth bonding pads PAD4_1-PAD4_{—}m, the core circuit 1311, the first resistance unit 1312 and the second resistance unit 1313 in the chip/die 1310 can be fabricated through any chip manufacturing process. The low-pass circuit 1321 in the package 1320 can be fabricated through any non-chip manufacturing process, for example, a packaging process or a surface-mounting device (SMD) process. The first pin PIN1 is electrically connected to the first bonding pad PAD1, and the second pin PIN2 is electrically connected to the third bonding pad PAD3.

Description of a transmission channel 1330 can be deduced according to related description of the transmission channel 120 of FIG. 1 or the transmission channel 230 of FIG. 2. In different application situations, the transmission channel 1330 can be a signal wire on a printed circuit board (PCB), or a cable wire (for example, a coaxial cable, an Ethernet cable or other cables). Signals can be transmitted through the transmission channel 1330. For example, differential signals output by the core circuit 1311 can be transmitted to a receiver circuit (not shown) through the first bonding pad PAD1, the third bonding pad PAD3, the first pin PIN1, the second pin PIN2 and the transmission channel 1330. For another example, signals output by a transmitter circuit (not shown) can be transmitted to the core circuit 1311 through the transmission channel 1330, the first pin PIN1, the second pin PIN2, the first bonding pad PAD1 and the third bonding pad PAD3.

Generally, the transmission channel 1330 has a characteristic of a low-pass filter. Namely, a signal gain in the transmission channel 1330 is decreased along with increase of signal frequency. By using the first resistance unit 1312 and the second resistance unit 1313 of the chip/die 1310 and the low-pass circuit 1321 of the package 1320, a gain amount of the low-frequency component of the differential signals on the first bonding pad PAD1 and the third bonding pad PAD3 is decreased. Therefore, the IC shown in FIG. 13 may have a passive equalizer function, so as to improve signal transmission integrity. In some other embodiments, resistances of the first resistance unit 1312 and the second resistance unit 1313 can be adjusted to implement the passive equalizer function of adaptive bandwidth, so as to adjust a frequency response characteristic thereof.

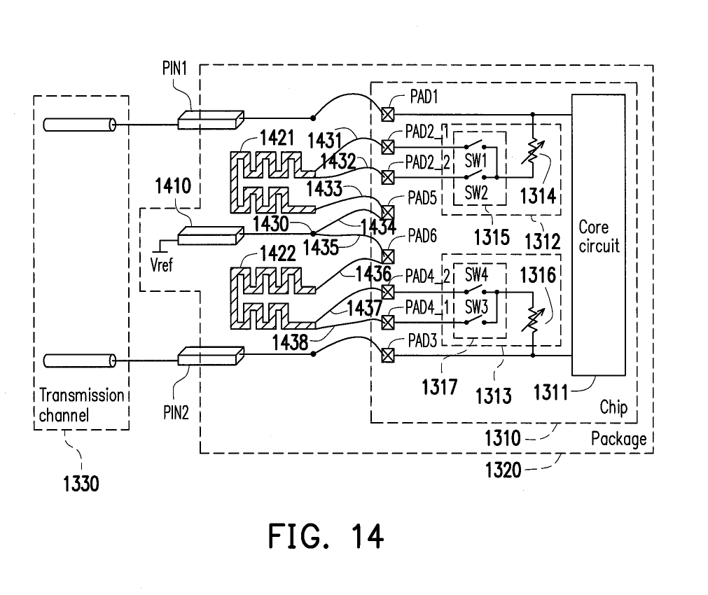

FIG. 14 is a schematic diagram of an IC according to another embodiment of the invention. Description of the embodiment of FIG. 14 can be deduced according to related description of the embodiment of FIG. 13. In the embodiment of FIG. 14, the chip/die 1310 includes a bonding pad PAD1, a bonding PAD2_1, a bonding pad PAD2_2, a bonding pad PAD3, a bonding pad PAD4_1, a bonding pad PAD4_2, a bonding pad PAD5, a bonding pad PAD6, a core circuit 1311, a first resistance unit 1312 and a second resistance unit 1313. The first resistance unit 1312 includes a resistor 1314 and a routing circuit 1315. The routing circuit 1315 includes a first switch SW1 and a second switch SW2. A first end of the resistor 1314 is coupled to the first bonding pad PAD1. First ends of the first switch SW1 and the second switch SW2 are coupled to a second end of the resistor 1314. A second end of the first switch SW1 is coupled to the bonding pad PAD2_1. A second end of the second switch SW2 is coupled to the bonding pad PAD2_2. The second resistance unit 1313 includes a resistor 1316 and a routing circuit 1317. The routing circuit 1317 includes a third switch SW3 and a fourth switch SW4. A first end of the resistor 1316 is coupled to the third bonding pad PAD3. First ends of the third switch SW3 and the fourth switch SW4 are coupled to a second end of the resistor 1316. A second end of the third switch SW3 is coupled to the bonding pad PAD4_1. A second end of the fourth switch SW4 is coupled to the bonding pad PAD4_2.

The low-pass circuit 1321 includes a pin 1410, a first high impedance wire 1421, a second high impedance wire 1422, a common node 1430, a first bonding wire 1431, a second bonding wire 1432, a third bonding wire 1433, a fourth bonding wire 1434, a fifth bonding wire 1435, a sixth bonding wire 1436, a seventh bonding wire 1437 and an eighth bonding wire 1438. Two ends of the first bonding wire 1431 are electrically connected to the bonding pad PAD2_1 of the chip/die 1310 and a first end of the first high impedance wire 1421 of the package 1320, respectively. Two ends of the second bonding wire 1432 are electrically connected to the bonding pad PAD2_2 of the chip/die 1310 and the first end of the first high impedance wire 1421 of the package 1320, respectively. Two ends of the third bonding wire 1433 are electrically connected to the bonding pad PAD5 of the chip/die 1310 and a second end of the first high impedance wire 1421 of the package 1320, respectively. Two ends of the fourth bonding wire 1434 are electrically connected to the bonding pad PAD5 of the chip/die 1310 and the common node 1430 of the package 1320, respectively. Two ends of the fifth bonding wire 1435 are electrically connected to the bonding pad PAD6 of the chip/die 1310 and the common node 1430 of the package 1320, respectively. Two ends of the sixth bonding wire 1436 are electrically connected to the bonding pad PAD6 of the chip/die 1310 and a first end of the second high impedance wire 1422 of the package 1320, respectively. Two ends of the seventh bonding wire 1437 are electrically connected to the bonding pad PAD4_2 of the chip/die 1310 and a second end of the second high impedance wire 1422 of the package 1320, respectively. Two ends of the eighth bonding wire 1438 are electrically connected to the bonding pad PAD4_1 of the chip/die 1310 and the second end of the second high impedance wire 1422 of the package 1320, respectively.

The first switch SW1 and the second switch SW2 may couple the resistor 1314 to the bonding pad PAD2_1 and/or the bonding pad PAD2_2. The third switch SW3 and the fourth switch SW4 may couple the resistor 1316 to the bonding pad PAD4_1 and/or the bonding pad PAD4_2. Therefore, the routing circuit 1315 and the routing circuit 1317 may determine an impedance between the bonding pad PAD1 and the bonding pad PAD3. For example, it is assumed that the bonding wires 1431-1438 respectively have an inductance of 1 nH, and the high impedance wires 1421 and 1422 respectively have an inductance of 2 nH. When the switches SW1-SW4 are all turned on, the impedance between the bonding pad PAD1 and the bonding pad PAD3 is about 0.5+2+1+1+1+1+2+0.5=9 nH (not including the resistors 1314 and 1316). When the switches SW1 and SW3 are turned on, and the switches SW2 and SW4 are turned off, the impedance between the bonding pad PAD1 and the bonding pad PAD3 is about 1+2+1+1+1+1+2+1=10 nH (not including the resistors 1314 and 1316).

In the embodiment of FIG. 14, the common node 1430 is electrically connected to the pin 1410. The pin 1410 can be coupled to the reference voltage Vref (for example, the ground voltage or other fixed voltage). In the embodiment of FIG. 14, the reference voltage Vref can be provided by a regulator in internal of the chip/die 710 (or in internal of the package 720). In other embodiments, the reference voltage Vref can be provided by a voltage source outside the package 720. In another embodiment, the pin 1410 can be floated (which is not coupled to the reference voltage Vref). In other embodiments, the pin 1410 can be omitted.

In summary, the integrated circuit is configured to have a passive equalizer function of adaptive bandwidth, so as to improve transmission integrity of differential signals. By using the resistance unit configured in the chip/die and the passive low-pass circuit configured in the package structure (outside the chip/die), the passive equalizer function with adjustable frequency response characteristic is implemented.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. An integrated circuit, comprising:
a chip or die, comprising a first bonding pad, a second bonding pad, a core circuit and a first resistance unit, wherein the first bonding pad is coupled to a first signal path of the core circuit, and two ends of the first resistance unit are respectively coupled to the first bonding pad and the second bonding pad; and
a package, comprising a first pin and a low-pass circuit, wherein the chip or die is disposed in the package, the first pin is electrically connected to the first bonding pad, and a first terminal of the low-pass circuit is electrically connected to the second bonding pad.

2. The integrated circuit as claimed in claim 1, wherein the first resistance unit comprises a variable resistor.

3. The integrated circuit as claimed in claim 1, wherein the first pin is electrically connected to the first bonding pad through wire bonding, and the low-pass circuit is electrically connected to the second bonding pad through wire bonding.

4. The integrated circuit as claimed in claim 1, wherein the low-pass circuit comprises:
a reference pin, coupled to a reference voltage; and
a bonding wire, having two ends electrically connected to the second bonding pad of the chip or die and the reference pin of the package, respectively.

5. The integrated circuit as claimed in claim 1, wherein the low-pass circuit comprises:
a high impedance wire, having a first end coupled to a reference voltage; and
a bonding wire, having two ends electrically connected to the second bonding pad of the chip or die and a second end of the high impedance wire of the package, respectively.

6. The integrated circuit as claimed in claim 5, wherein the high impedance wire is set as a coil.

7. The integrated circuit as claimed in claim 1, wherein the low-pass circuit comprises:
an inductor, having a first end coupled to a reference voltage; and
a bonding wire, having two ends electrically connected to the second bonding pad of the chip or die and a second end of the inductor of the package, respectively.

8. The integrated circuit as claimed in claim 1, wherein the low-pass circuit comprises:
a high impedance wire, wherein a first end of the high impedance wire is coupled to a reference voltage, and a second end of the high impedance wire is electrically connected to the second bonding pad of the chip or die through a conductive bump.

9. The integrated circuit as claimed in claim 1,
wherein the chip or die further comprises a third bonding pad, a fourth bonding pad and a second resistance unit, wherein the third bonding pad is coupled to a second signal path of the core circuit, the first signal path and the second signal path are differential signal pair, and two ends of the second resistance unit are respectively coupled to the third bonding pad and the fourth bonding pad; and
the package further comprises a second pin, wherein the second pin is electrically connected to the third bonding pad, and a second end of the low-pass circuit is electrically connected to the fourth bonding pad.

10. The integrated circuit as claimed in claim 9, wherein the first resistance unit and the second resistance unit respectively comprise a variable resistor.

11. The integrated circuit as claimed in claim 9, wherein the first pin and the second pin are electrically connected to the first bonding pad and the third bonding pad through wire bonding respectively, and two ends of the low-pass circuit are electrically connected to the second bonding pad and the fourth bonding pad through wire bonding respectively.

12. The integrated circuit as claimed in claim 9, wherein the low-pass circuit comprises:
a third pin;
a first bonding wire, having two ends electrically connected to the second bonding pad of the chip or die and the third pin of the package, respectively; and
a second bonding wire, having two ends electrically connected to the fourth bonding pad of the chip or die and the third pin of the package, respectively.

13. The integrated circuit as claimed in claim 12, wherein the third pin is floated or is coupled to a reference voltage.

14. The integrated circuit as claimed in claim 9, wherein the low-pass circuit comprises:
a low impedance wire;
a first bonding wire, having two ends electrically connected to the second bonding pad of the chip or die and a first end of the low impedance wire of the package, respectively; and
a second bonding wire, having two ends electrically connected to the fourth bonding pad of the chip or die and a second end of the low impedance wire of the package, respectively.

15. The integrated circuit as claimed in claim 14, wherein the low-pass circuit further comprises:
a third pin, electrically connected to the first end of the low impedance wire; and
a fourth pin, electrically connected to the second end of the low impedance wire;
wherein the third pin and the fourth pin are coupled to a reference voltage.

16. The integrated circuit as claimed in claim 9, wherein the low-pass circuit comprises:
a high impedance wire;
a first bonding wire, having two ends electrically connected to the second bonding pad of the chip or die and a first end of the high impedance wire of the package, respectively; and
a second bonding wire, having two ends electrically connected to the fourth bonding pad of the chip or die and a second end of the high impedance wire of the package, respectively.

17. The integrated circuit as claimed in claim 16, wherein the high impedance wire is set as a coil.

18. The integrated circuit as claimed in claim 16, wherein the low-pass circuit further comprises:
a third pin, wherein a central end of the high impedance wire is electrically connected to the third pin.

19. The integrated circuit as claimed in claim 9, wherein the low-pass circuit comprises:
an inductor;
a first bonding wire, having two ends electrically connected to the second bonding pad of the chip or die and a first end of the inductor of the package, respectively; and
a second bonding wire, having two ends electrically connected to the fourth bonding pad of the chip or die and a second end of the inductor of the package, respectively.

20. The integrated circuit as claimed in claim 19, wherein the low-pass circuit further comprises:
a third pin, wherein a center-tapped terminal of the inductor is electrically connected to the third pin.

21. The integrated circuit as claimed in claim 9, wherein the low-pass circuit comprises:
a high impedance wire, wherein a first end of the high impedance wire is coupled to the second bonding pad of the chip or die through a first conductive bump, and a second end of the high impedance wire is electrically connected to the fourth bonding pad of the chip or die through a second conductive bump.

22. The integrated circuit as claimed in claim 9, wherein the chip or die comprises a plurality of second bonding pads, the second bonding pads are electrically connected to a plurality of first terminals of the low-pass circuit according to a connection relationship, and the first resistance unit comprises:
a resistor, having a first end coupled to the first bonding pad; and
a routing circuit, having a common terminal coupled to a second end of the resistor, and a plurality of selection terminals coupled to the second bonding pads in a one-to-one manner;
wherein the routing circuit couple the common terminal to one or a plurality of the selection terminals, and the routing circuit adjusts a serial or parallel configuration state of the wire bonding on the second bonding pads to determine an impedance.

23. The integrated circuit as claimed in claim 9, wherein the chip or die further comprises a fifth bonding pad, a sixth bonding pad, a seventh bonding pad and an eighth bonding pad, the first resistance unit comprises a first resistor, a first switch and a second switch, the second resistance unit comprises a second resistor, a third switch and a fourth switch, and the low-pass circuit comprises a first high impedance wire, a second high impedance wire, a common node, a first bonding wire, a second bonding wire, a third bonding wire, a fourth bonding wire, a fifth bonding wire, a sixth bonding wire, a seventh bonding wire and an eighth bonding wire;
wherein a first end of the first resistor is coupled to the first bonding pad, and a second end of the first resistor is coupled to a first end of the first switch and a first end of the second switch;
wherein a second end of the first switch is coupled to the second bonding pad;
wherein a second end of the second switch is coupled to the fifth bonding pad;
wherein a first end of the second resistor is coupled to the third bonding pad, and a second end of the second resistor is coupled to a first end of the third switch and a first end of the fourth switch;
wherein a second end of the third switch is coupled to the fourth bonding pad;
wherein a second end of the fourth switch is coupled to the sixth bonding pad;
wherein two ends of the first bonding wire are electrically connected to the second bonding pad of the chip or die and a first end of the first high impedance wire of the package, respectively;
wherein two ends of the second bonding wire are electrically connected to the fifth bonding pad of the chip or die and the first end of the first high impedance wire of the package, respectively;
wherein two ends of the third bonding wire are electrically connected to the seventh bonding pad of the chip or die and a second end of the first high impedance wire of the package, respectively;
wherein two ends of the fourth bonding wire are electrically connected to the seventh bonding pad of the chip or die and the common node of the package, respectively;
wherein two ends of the fifth bonding wire are electrically connected to the eighth bonding pad of the chip or die and the common node of the package, respectively;
wherein two ends of the sixth bonding wire are electrically connected to the eighth bonding pad of the chip or die and a first end of the second high impedance wire of the package, respectively;
wherein two ends of the seventh bonding wire are electrically connected to the sixth bonding pad of the chip or die and a second end of the second high impedance wire of the package, respectively; and
wherein two ends of the eighth bonding wire are electrically connected to the fourth bonding pad of the chip or die and the second end of the second high impedance wire of the package, respectively.

24. The integrated circuit as claimed in claim 9, wherein the first bonding pad and the third bonding pad are disposed between the second bonding pad and the fourth bonding pad.
